(19) United States
(12) Patent Application Publication
(10) Pub. No.: US 2025/0081432 A1
(43) Pub. Date: Mar. 6, 2025

(54) GATE ALL AROUND 4F2 DRAM

(71) Applicant: Applied Materials, Inc., Santa Clara, CA (US)

(72) Inventors: Zhijun CHEN, San Jose, CA (US); Fredrick FISHBURN, Aptos, CA (US); Tong LIU, Folsom, CA (US); Sony VARGHESE, Manchester, MA (US); Balasubramanian PRANATHARTHIHARAN, San Jose, CA (US)

(73) Assignee: Applied Materials, Inc., Santa Clara, CA (US)

(21) Appl. No.: 18/816,103

(22) Filed: Aug. 27, 2024

Related U.S. Application Data
(60) Provisional application No. 63/580,562, filed on Sep. 5, 2023.

(51) Int. Cl. H10B 12/00; H01L 21/762; H01L 29/06; H01L 29/423; H01L 29/66; H01L 29/775; H01L 29/786

(52) U.S. Cl. CPC H10B 12/315; H01L 21/76224; H10B 12/05; H10B 12/482; H10B 12/488; H10D 30/014; H10D 30/43; H10D 30/6735; H10D 30/6757; H10D 62/121

(57) ABSTRACT

Vertical cell dynamic random-access memory (DRAM) arrays and methods of forming arrays with improved stability and word line resistivity are provided. The arrays include a plurality of bit lines arranged in a first horizontal direction and a plurality of word lines arranged in a second horizontal direction. The arrays include a plurality of channels extending in a vertical direction generally orthogonal to the first direction and the second horizontal direction, such that the plurality of bit lines intersect with a source/drain region of the plurality of channels. In addition, arrays include a bridge extending between a first channel of the plurality of channels and a second channel of the plurality of channels, where the first channel is spaced apart from the second channel in a row extending in the second horizontal direction. Arrays include a gate formed around at least a portion of the plurality of channels and the bridge.

### CROSS-REFERENCES TO RELATED APPLICATIONS

This application claims the benefit of priority to U.S. patent application Ser. No. 63/580,562 filed Sep. 5, 2023, the contents of which are hereby incorporated by reference in their entirety for all purposes.

### TECHNICAL FIELD

This disclosure generally describes designs for a 4F² two-dimensional dynamic random access memory array. More specifically, this disclosure describes a gate-all-around (“GAA”) 4F² memory array with improved gate control, word line resistance and structural stability.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. The manufacturing of a DRAM cell includes the fabrication of a transistor, a capacitor, and three contacts: one each to the bit line, the word line, and the reference voltage. There is a continuous desired to decrease the size of individual cells and to increase memory cell density to allow more memory to be included on a single memory chip. However, further increases in density have proven problematic.

In addition, in the 4F² DRAM scheme, the storage node (capacitor) and bit line are located at the top and bottom of a vertical cell transistor, leaving the channel completely isolated from the body. Due to this arrangement, the floating body effect, which is not an issue for current 8F² or 6F² DRAM cell architecture due to the body connection of the channels, becomes a major technical challenge for 4F² DRAM. Therefore, improvements in the art are needed.

### BRIEF SUMMARY

The present technology is generally directed to vertical cell dynamic random-access memory (DRAM) arrays and methods of forming such arrays. Arrays include a plurality of bit lines arranged in a first horizontal direction, a plurality of channels extending in a vertical direction, a bridge extending between a first channel of the plurality of channels and a second channel of the plurality of channels, and a gate extending in the second horizontal direction. Arrays include where the vertical direction is generally orthogonal to the first horizontal direction such that the plurality of bit lines intersect with a source/drain region of the plurality of channels. Arrays include where the first channel is spaced apart from the second channel in a row extending in the second horizontal direction. Arrays include where the gate is formed around at least a portion of the plurality of channels and the bridge.

In embodiments, arrays include where the gate extends between the first channel and the second channel at a location above the bridge, below the bridge, and/or both above and below the bridge. In embodiments, the gate has a thickness of less than or about 8 nm. In more embodiments, the gate has a thickness than is less than 50% of a gap width between the first the first channel and the second channel. Furthermore, in embodiments, the bridge is formed from a dielectric material. Additionally or alternatively, in embodiments, the bridge is formed from a substrate material. In yet more embodiments, the bridge is formed from a p-doped substrate material. In further embodiments, arrays include at least a third channel of the plurality of channels paced apart from the second channel in the row extending in the second horizontal direction, where a second bridge extends between the second channel and the third channel. In embodiments, the gate extends around the second bridge. Moreover, in embodiments, the first channel and the second channel define a channel height between a first source/drain region of the respective channel and a top surface of the respective channel, where the bridge is disposed between the first channel and the second channel at a height that is from about 20% to about 80% of the channel height.

The present technology is also generally directed to arrays having a plurality of bit lines arranged in a first horizontal direction, a plurality of word lines arranged in a second horizontal direction, a first plurality of spaced apart channels extending in a first row extending in the second horizontal direction, a second plurality of spaced apart channels in a second row extending in the second horizontal direction, spaced apart from the first row, a plurality of bridges extending between adjacent channels in the first row and between adjacent channels in the second row, and one or more gates. Arrays include where the one or more gates extend around the first plurality of spaced apart channels and the plurality of bridges in the first row, and the second plurality of spaced apart channels and the plurality of bridges in the second row, or both the first plurality of spaced apart channels and the plurality of bridges in the first row and the second plurality of spaced apart channels and the plurality of bridges in the second row. Arrays include where each of the channels extends in a vertical direction that is generally orthogonal to the first horizontal direction and the second horizontal direction such that the plurality of bit lines intersect with a source/drain region of the plurality of channels.

In embodiments, the one or more gates extends between adjacent channels in the first row and/or the second row at a location above the bridge, below the bridge, and/or both above and below the bridge. In more embodiments, the one or more gates have a thickness that is less than 50% of a gap width between adjacent channels in the first row and/or second row.

The present technology is also generally directed to methods for forming arrays. Methods include etching a substrate to form one or more shallow trench isolations extending in a first horizontal direction and a plurality of vertically extending walls having a first source/drain region at a second end of the vertically extending walls. Methods include forming a dielectric material in the one or more shallow trench isolations and recessing the dielectric material to a first depth in the one or more shallow trench isolations. Methods include forming a bridge in the one or more shallow trench isolations that contacts a first sidewall of a first wall and a second sidewall of a second wall of the plurality of vertically extending walls. Methods include depositing a mask over a first end of the vertically extending walls and etching one or more second trenches in a second horizontal direction, forming at least a first channel and a second channel. Methods include depositing a gate material around the first channel, the second channel, and the bridge.

In embodiments, the gate material is deposited at a thickness of less than 50% of a width of one or more of the second trenches. In more embodiments, the gate material is deposited until a gate material deposited around the first channel and a gate material deposited around the second channel merge in the respective shallow trench isolation. Furthermore, in embodiments, methods include removing at least a portion of the gate material in the one or more second trenches. Additionally or alternatively, in embodiments, methods include maintaining the mask during etching of the one or more second trenches and the depositing of the gate material. In embodiments, methods include recessing the bridge from a first height to a second height below the first height prior to depositing the gate material. In yet more embodiments, methods include forming a protective liner in the one or more shallow trench isolations after recessing the dielectric oxide to a first depth, and recessing the dielectric oxide to a second depth in the one or more shallow trench isolations below the first depth.

Such technology may provide numerous benefits over conventional systems and techniques. For example, the processes and systems may provide for a GAA 4F² DRAM device, and particularly a GAA 4F² DRAM device with reduced floating body effect. Additionally, the processes and systems herein allow for improved resistance, such as reduced word line resistance. Furthermore, processes and systems herein may provide increased stability in a GAA 4F² DRAM device. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a perspective view of a semiconductor structure according to embodiments of the present technology with a dielectric material fill after first shallow trench isolation formation.

FIG. 3B shows a perspective view of a semiconductor structure according to embodiments of the present technology with a recessed dielectric material.

FIG. 3C shows a perspective view of a semiconductor structure according to embodiments of the present technology with a protective liner.

FIG. 3D shows a perspective view of a semiconductor structure according to embodiments of the present technology with the protective liner bottom removed.

FIG. 3E shows a perspective view of a semiconductor structure according to embodiments of the present technology with the dielectric material etched back.

FIG. 3F shows a perspective view of a semiconductor structure according to embodiments of the present technology where the exposed substrate has been cleaned.

FIG. 3G shows a perspective view of a semiconductor structure according to embodiments of the present technology with bridges formed between adjacent channels.

FIG. 3H shows a perspective view of a semiconductor structure according to embodiments of the present technology with the bridge recessed.

FIG. 31 shows a perspective view of a semiconductor structure according to embodiments of the present technology with a fill over the bridge.

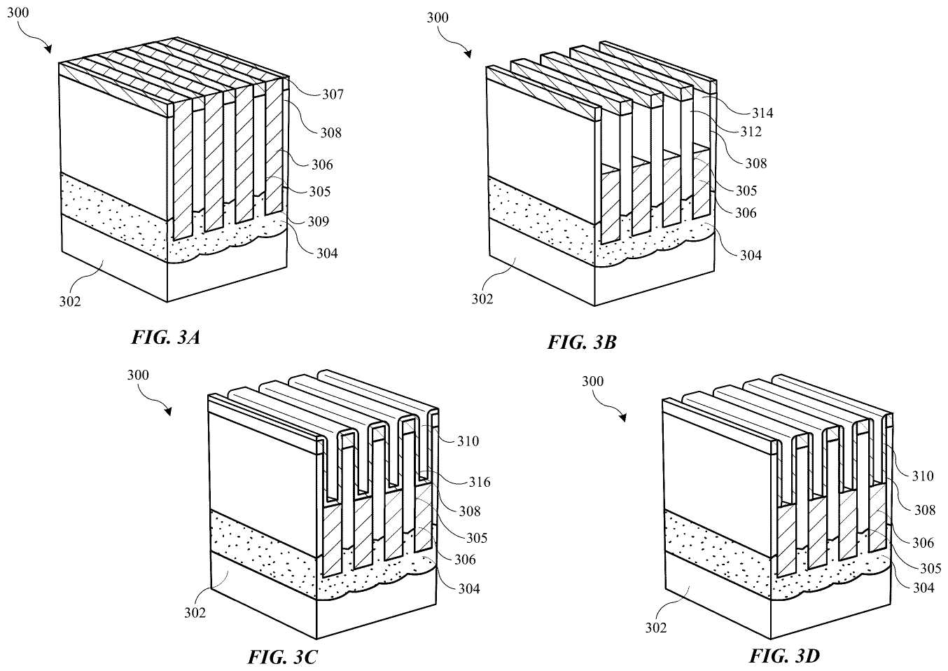

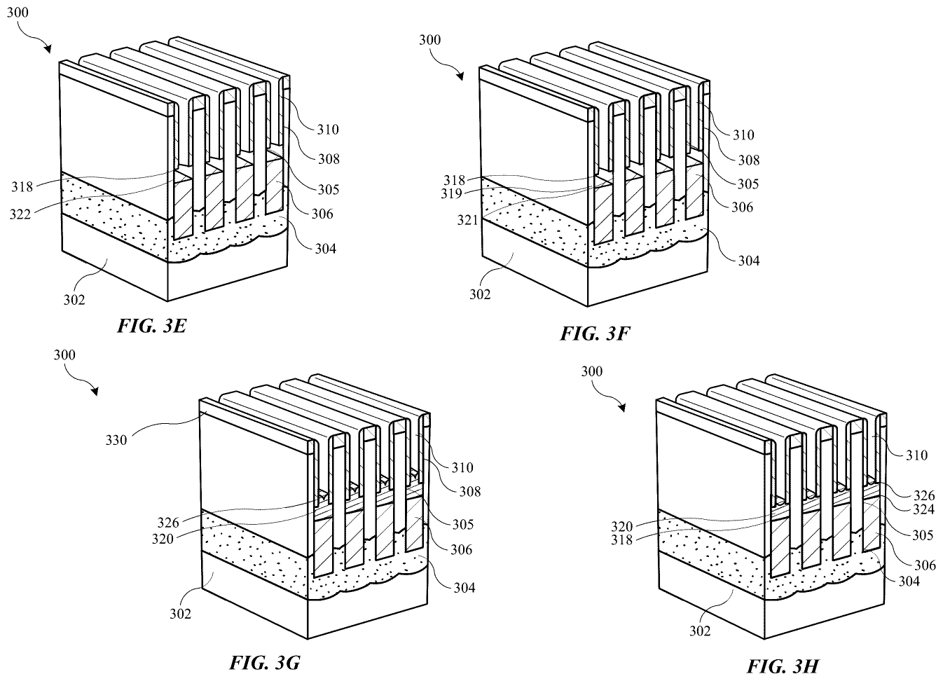

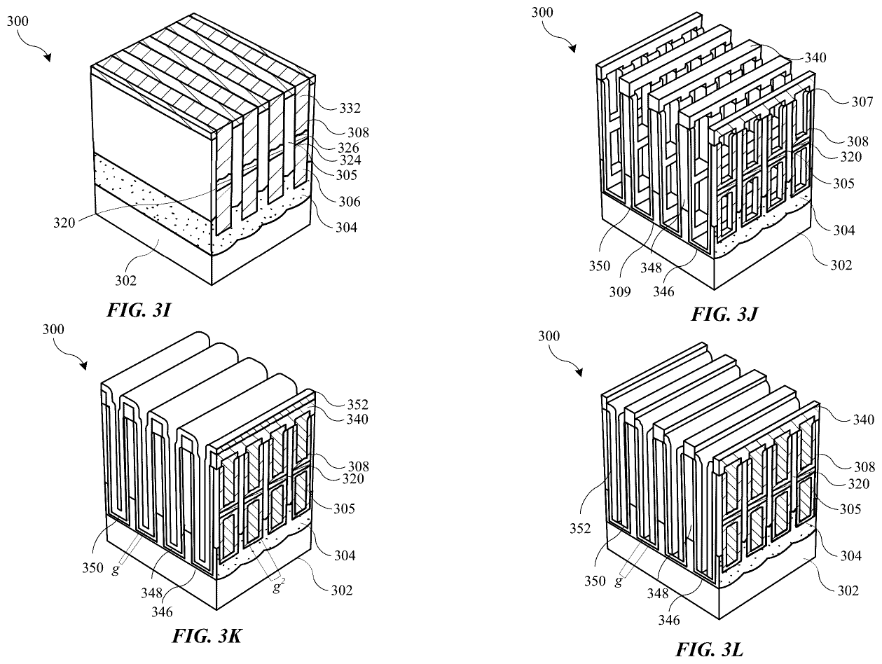

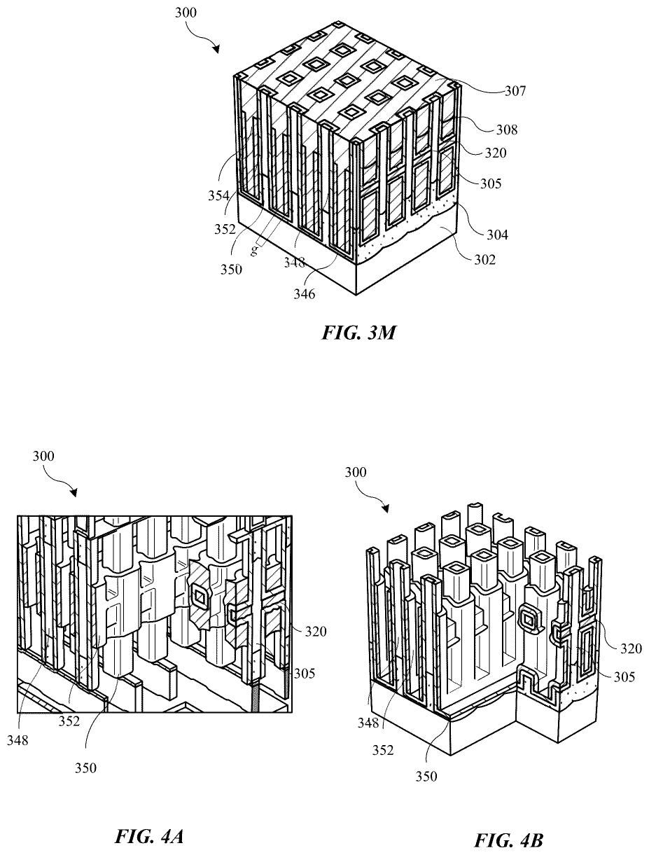

FIG. 3J shows a perspective view of a semiconductor structure according to embodiments of the present technology etched in the word line direction and with the fill removed.

FIG. 3K shows a perspective view of a semiconductor structure according to embodiments of the present technology with gate metal deposited.

FIG. 3L shows a perspective view of a semiconductor structure according to embodiments of the present technology with the bottom opened and optionally trimmed.

FIG. 3M shows a perspective view of a semiconductor structure according to embodiments of the present technology.

FIG. 4A shows a perspective view of a semiconductor structure according to embodiments of the present technology.

FIG. 4B shows a perspective view of a semiconductor structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities had been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F₂ DRAM are greatly reduced as compared to 6F². This is due at least in part to the fact that in the 4F₂ DRAM scheme, the capacitor and bit line are located at two ends of a vertical cell transistor, instead of tightly packed on the same side as in 6F² DRAM.

However, the 4F² DRAM design comes with its own challenges. For example, 4F² memory cells have the transistor channel disposed between the bitline and the capacitor layers, leaving no common substrate connecting the channels, resulting in a floating body effect for these transistors. For instance, it is believed that conventional 4F² DRAM devices exhibit off-leakage current issues. Off-leakage current results from the floating body effect, such as hole accumulation in the body of a 4F² DRAM device due to the isolated channels. For instance, electron-hole pairs can form in a semiconductor channels due to band-to-band tunneling. While the electrons can flow into the n-type source or drain regions of the transistor, the holes cannot. For 4F² DRAM devices without a substrate connection, the holes have no path to leave the channel and will continue to accumulate. Thus, the floating body effect may lead to channel activation without gate activation, which eventually translates into leakage current from the capacitor, or data storage side of the device. Attempts have been made to provide body connections utilizing a buried body contact scheme. However, such attempts can result in gate overlap to a source/drain junction edge, allowing undesired gate-induced drain leakage, or limited scalability to small dimensions. Moreover, such design schemes are also capable of producing high aspect ratio structures that challenge existing doping techniques.

In addition, GAA 4F² DRAM devices have proved to exhibit further difficulties. For instance, as 4F² DRAM devices have continued to decrease in feature size and pitch, forming an adequate gate connection has proved problematic. Specifically, due to the decreased gap between adjacent word lines, merging between adjacent word lines is exhibited before or during merging of the gate material between adjacent channels in the word line direction. Such a defect causes electrical defects, such as shorting. Attempts to avoid such deficiencies have included depositing less gate material. However, such attempts can result in high resistivity due at least in part to an inadequate merge between adjacent channels. Moreover, attempts have been made to trim the excess gate material from the word line trench. However, trimming requires sufficient distance between adjacent word lines within the respective trench, proving inadequate for increasingly scaled devices.

Furthermore, GAA 4F² DRAM devices also exhibit poor structural stability during formation. Unlike other 4F² DRAM devices, the oxide is removed prior to gate formation, leaving respective channels with little to no support during word line formation. Such poor stability can result in device inconsistencies and defects, leading to poor electrical properties.

The present technology overcomes these and other problems by connecting two or more channels of a vertically arranged transistor in a respective row of cells with a bridge outside of the source/drain region(s) of the transistor. Namely, a bridge between channels along the gate, or word-line direction, provides a support that may also be utilized as a platform to deposit one or more gate materials. Such a support reduces the necessary thickness of the gate material(s), as a robust connection may be formed with or without full merging between adjacent channels. In addition, it was surprisingly found that such a support improves word line resistivity, as the support allows for consistent and controlled gate thickness across the support, and therefore between adjacent channels in a word line direction. Moreover, such a support also allows for greatly improved structural stability during word line (and thus also subsequent 4F² feature) formation, resulting in improved consistency and reduced defects in the resulting device. Furthermore, in some embodiments, such as support may provide a pathway for hole movement between channels when the gate is off, reducing the floating body effect impact on a defective channel. Thus, the present technology may also provide for reduction in the floating body effect without disrupting the size or connections of the 4F² DRAM device.

Although the remaining disclosure will routinely identify specific deposition and etch processes utilized for forming vertical cell dynamic random-access memory (DRAM) arrays, such as a GAA 4F² DRAM device, it will be readily understood that the systems and methods are equally applicable to other DRAM devices, other GAA devices, other devices suffering from a floating body effect or poor stability, and orientations thereof, as well as processes for forming such devices. Accordingly, the technology should not be considered to be so limited as for use with these specific devices or systems alone. The disclosure will discuss one possible semiconductor device that may include one or more components, utilizing one or more bridges according to embodiments of the present technology before additional variations and adjustments to this apparatus according to embodiments of the present technology are described.

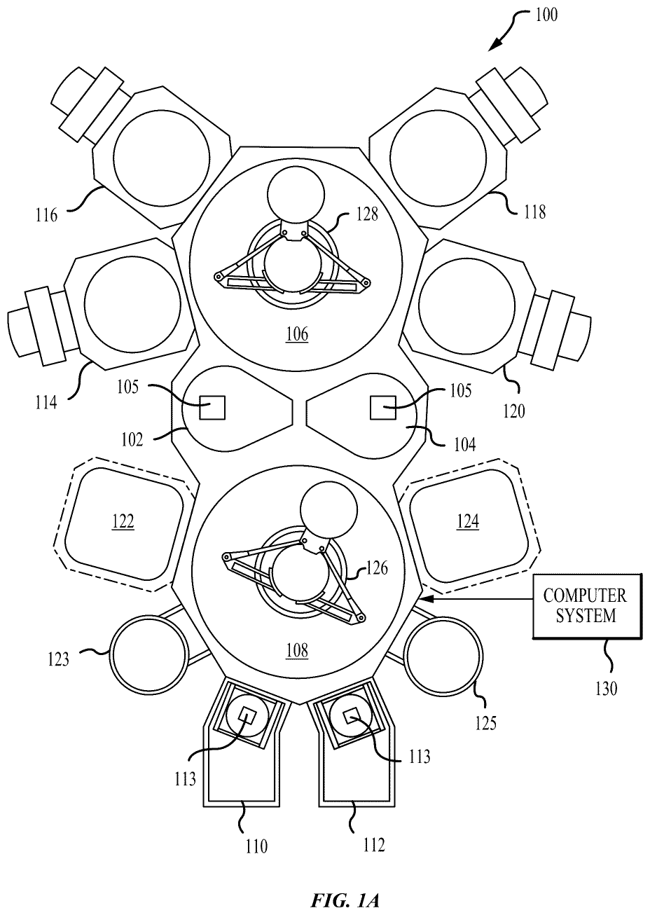

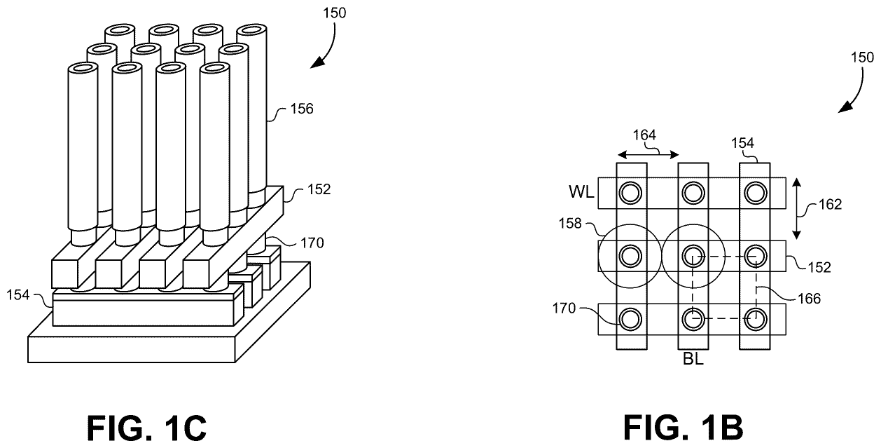

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor 170, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors 170 and capacitors in a rectangular generally orthogonal grid pattern (where generally orthogonal may be within about 10° from orthogonal, such as less than or about 7.5°, such as less than or about 5°, such as less than or about 2.5°, such as less than or about 1° from orthogonal, or any ranges or values therebetween), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

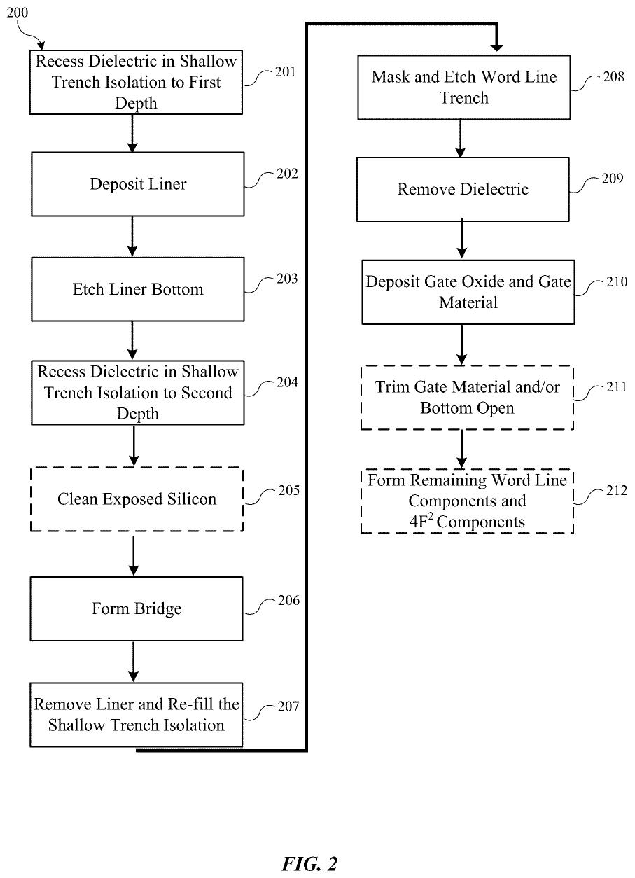

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically from the word line side of the structure to the bit line side of the structure, it should be understood that the other orientation from bit line to word line side may be utilized.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in FIGS. 3A-3M, the illustrations of which will be described in conjunction with the operations of method 200. It is to be understood that FIG. 3A-3M illustrate only partial schematic views, and a semiconductor substrate may include further components as illustrated in the figures, as well as alternative components, of any size or configuration that may still benefit from aspects of the present technology.

Method 200 may or may not involve optional operations to develop the semiconductor structure to a particular fabrication operation. It is to be understood that method 200 may be performed on any number of semiconductor structures 300 or substrates 302, as illustrated in FIG. 3A-3M, including exemplary structures on which a selective deposition material may be formed. As illustrated in FIG. 3A substrate 302 may be any number of materials, such as a base wafer or substrate made of silicon or silicon-containing materials, germanium, other substrate materials, as well as one or more materials that may be formed overlying the substrate during semiconductor processing.

In embodiments, the structure 300 may be a semiconductor substrate, including bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100>or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor clement during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

As illustrated in FIG. 3A, structure 300 is provided that includes a substrate 302 that has already undergone source/drain 304 formation, shallow trench isolation formation 308, and first dielectric material 306 fill in shallow trench isolations 308. In addition, two or more silicon walls 305 are formed between respective shallow trench isolations 308, where the illustrated walls 305 are spaced apart in a horizontally extending row parallel to a word line direction in this embodiment. In embodiments, source/drain 304 formation may include one or more ion implants followed by a subsequent anneal process. The implant process may be a single implant or may include a series of multiple implants. When multiple implants are utilized, each implant may utilize the same ion, or different ions. Although, it should be understood that the source/drain region 304 may be formed from any suitable process, including after formation of the front-side device, as will be discussed below. The method may include providing a semiconductor structure having first source/drain regions 304 for a plurality of vertical channels, and forming a plurality of word lines that contact the first source/drain regions. Overall, this process may incrementally form each stage of the transistor on top of a previous completed stage.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

Nonetheless, at operation 201, method 200 may include recessing the first dielectric material 306 to a first recessed depth in one or more of the shallow trench isolations 308 as illustrated in FIG. 3B. For instance, in embodiments, a substrate 302 may be loaded into load lock 110,112 and transferred to a process chamber (such as process chamber 114) via robots 126, 128, where first dielectric material 306 is recessed. It should be understood that the substrate may be transferred between each operation step, or only a portion of the operation steps, as some operation steps may be completed in the same processing chamber. In embodiments, the dielectric material may be recessed to an approximate midpoint of the respective shallow trench isolation 308. However, it should be understood that the first dielectric material 306 may be recessed to a depth that is about 20% to about 80% of the depth of each respective shallow trench isolation 308, such as from about 30% to about 70%, such as from about 40% to about 60%, such as from about 45% to about 55%, or any ranges or values therebetween. Namely, each shallow trench isolation 308 defined between adjacent channels has a first end 307 and a second end 309 and defines a trench depth therebetween. Moreover, recessing operation 201 may be conducted by any method as known in the art.

As illustrated in FIG. 3C, after recessing operation 201, a protective liner 310 is formed over recessed first dielectric material 306 and an exposed portion of the first sidewall 312 and the second sidewall 314 (shown more clearly in FIG. 3B) of each shallow trench isolation 308 at operation 202. The protective liner 310 may be formed from any dielectric material having a different etch rate than first dielectric material 306 as known in the art, such as a silicon nitride, a silicon oxynitride, silicon dioxide, or other similar materials. Additionally or alternatively, in embodiments, the protective liner 310 may be formed from the same material as first dielectric material 306, but has a thickness so as to retain at least a portion of the protective liner 310 after the second recessing operation 204. Nonetheless, as illustrated in FIG. 3D, after formation of the protective liner 310, the protective liner 310 bottom 316 may be etched out at operation 203 to expose first dielectric material 306. Such an etching process that selectively removes the bottom surface may be referred to as a “bottom punch”, also referred to as an anisotropic or directional etch. In embodiments, the selective bottom etching or bottom punching may be performed by any etch processes as known in the art, such as reactive ion etch.

Nonetheless, after bottom etching the protective liner 310, the first dielectric material 306 may undergo a second recessing step at operation 204. The recessing operation 204 may be selective for first dielectric material 306, without removing protective liner 310 from first sidewall 312 and second sidewall 314 of shallow trench isolation 308, or liner 310 may have a sufficient thickness to at least partially withstand the second recessing step. Namely, at least a portion of protective liner 310 remains on the first sidewall 312 and second sidewall 314. Regardless, first dielectric material 306 is etched from the first depth to a second depth below the first depth. By etching the first dielectric material 306 to a second depth, an exposed portion 322 of the first sidewall 312 and the opposed second sidewall 314 is formed between the first dielectric material 306 at the second depth and a bottom surface 318 of protective liner 310. In embodiments, the second depth is a distance below the first depth so as to provide a robust contact area for bridge 320.

Thus, in embodiments, the height difference from the first depth to the second depth, and/or the length of the exposed portion of first sidewall 312 and second sidewall 314 may be greater than or about 2 nm, such as greater than or about 4 nm, such as greater than or about 6 nm, such as greater than or about 8 nm, such as greater than or about 10 nm, such as greater than or about 12 nm, such as greater than or about 14 nm, such as greater than or about 16 nm, such as greater than or about 18 nm, such as greater than or about 20 nm, such as less than or about 50 nm, such as less than or about 45 nm, such as less than or about 40 nm, such as less than or about 35 nm, such as less than or about 30 nm, such as less than or about 25 nm, or any ranges or values therebetween. Namely, in embodiments, the distance and/or length may be selected so as to provide enough contact area for a robust physical and/or electrical connection, without being so large that the bridge 320 impacts the overall doping level of the wall 305 (or individual channels 348 discussed below), if a doped material is utilized for bridge 320.

Notwithstanding the depth of the dielectric material etched, the exposed portion 322 of first sidewall 312 and opposed second sidewall 314 is optionally cleaned at operation 205. The optional cleaning operation 205 may include a preclean operation and/or a surface damage removal operation. Namely, if it is desired for the bridge to improve hole distribution between channels, each bridge 320 may have a robust electrical connection with each of the adjacent walls 305. However, surface oxidation, damaged silicon from recessing operation 204, and other contaminants can prevent efficient merging of bridge 320 with first sidewall 312 and/or second sidewall 314. Thus, in embodiments, operation 205 includes selectively removing surface damage (e.g. silicon damaged during recessing operations, if any) from the exposed portion 322 of first sidewall 312 and second sidewall, such as with an isotropic etch process, as illustrated in FIG. 3F. An isotropic etch process, such as a gas-phase etch, is available from Applied Materials (Selectra™) which removes doped and undoped silicon while retaining dielectric materials. In embodiments, only one or more layers forming or adjacent to exposed surface 322 is/are removed. In embodiments, a preclean, such as a Siconi™ clean may remove any surface oxides present.

However, in embodiments, cleaning may not be necessary. Namely, in embodiments, method 200 may be conducted completely within processing system 100 without removal from vacuum, limiting the formation of oxides and other surface defects after oxide removal by recessing operation 204. Additionally or alternatively, no damaged silicon may be present after recessing operation 204. Moreover, in embodiments, it the bridge 320 may not contribute to hole distribution (e.g. is not formed form a material that provides an electrical connection) and may therefore not require an electrical connection to the adjacent channels. Thus, in embodiments, both a preclean and a surface damage removal operation may be utilized, only one of a preclean and a surface damage removal operation may be utilized, or neither a preclean or a surface damage removal operation may be utilized.

Method 200 further includes forming a bridge 320 between two adjacent walls 305 that extend along a single row (e.g. the bridge 320 is formed along or parallel to one or more gates, which will be discussed in greater detail below between a first sidewall 319 of a first wall 305 and a second sidewall 321 of a second wall 305, such as an exposed portion of the first and second sidewall) at operation 206, as illustrated in FIG. 3F and 3G. In embodiments, the bridge 320 may be formed from the same material as the two or more walls 305, or a different material suitable for forming a bridge between adjacent walls 305, such as any substrate material, dielectric material, or another material that can be deposited between adjacent walls 305 and provide structural support.

However, in embodiments where it is desired to improve the floating body effect, bridge 320 may be formed from a doped material that has a higher doping level than the walls 305 adjacent to the respective bridge 320. Namely, by utilizing a doping level higher than the walls 305 adjacent to the respective bridge, charge sharing between walls 305 via bridge 320 may be minimal or nonexistent when the walls 305 are biased on, as the voltage threshold is below the activation threshold of bridge 320. Nonetheless, the doping level must also not be significantly above the doping level of the two or more walls 305, as the dopant may diffuse into the two or more walls 305, raising the threshold of the channel above the bias voltage.

Thus, in embodiments, each of the bridges 320 may have a doping level that is greater than or about 1.6 times a doping level of the walls 305 adjacent to the respective bridge 320, such as greater than or about 1.8 times, such as greater than or about 2 times, such as greater than or about 2.2 times, such as greater than or about 2.4 times, such as greater than or about 2.6 times, such as greater than or about 2.8 times, such as greater than or about 3 times, such as less than or about 5 times, such as less than or about 4.8 times, such as less than or about 4.6 times, such as less than or about 4.4 times, such as less than or about 4.2 times, such as less than or about 4 times, such as less than or about 3.8 times, such as less than or about 3.6 times, such as less than or about 3.4 times, or any ranges or values therebetween.

Namely, as discussed above, when a doped material is utilized, each bridge 320 may have a sufficient doping level to prevent significant charge sharing, e.g., a level of doping sufficient to provide a Vt above a gate threshold for the walls 305 adjacent to the respective bridge. Nonetheless, as each bridge 320 has a higher level of dopant than the adjacent walls 305, each bridge 320 may diffuse dopant from the center of the respective bridge 320, towards and into the adjacent walls 305. The diffusion may therefore form a gradient of dopant from wall 305 towards the center of each bridge 320. Such a phenomena may improve hole attraction, reducing the floating body effect, as holes may move from problematic areas of one or more walls 305 into respective bridge 320, where the holes may be distributed across the bridge 320, or move fully along bridged rows between connected bridges 320 and walls 305, distributing the holes along a large area and dissipating the effects. However, if the doping level is too high in the one or more bridges 320 compared to adjacent walls 305, diffusion of dopant may increase the doping level of the one or more walls 305 to a level above a threshold value for the wall 305. Therefore, in embodiments, the doping level of each bridge compared to the adjacent walls 305 is carefully selected. Regardless, the present technology has surprisingly found that bridges 320 drastically reduce the floating body effect, such as by reducing channel potential increases and reducing off-leakage current.

Nonetheless, in embodiments, a number of different materials may be used for the one or more bridges 320. For example, the one or more bridges may include a crystalline semiconductor, such as silicon, germanium, silicon germanium, one or more dielectric materials, and/or other suitable structural support materials. In embodiments, the bridges may be formed from a crystalline silicon, such as a single crystalline silicon in embodiments, or any one or more of the semiconductor materials discussed above, dielectric materials, as well as any other materials that are suitable for deposition between adjacent channels to provide structural support. Nonetheless, these materials may also be used in a polycrystalline semiconductor form.

In embodiments, the one or more bridges 320 may be formed by epitaxially growing a bridge or support material on recessed first dielectric material 306 in shallow trench isolation 308, and merging the epitaxial layer until contact with both the first sidewall 312 and second sidewall 314 is achieved. Thus, in embodiments, such a processes may be referred to as a selective epi-deposition process. Alternatively, the one or more bridges 320 may be formed by conformally filling the shallow trench isolation 308 with one or more bridge or support materials, or by depositing one or more bridge or support materials utilizing other deposition methods known in the art. Regardless of the method used, it should be clear that the material used for the one or more bridges 320 is deposited or grown so as to provide good contact with the exposed portion 322 of both the first sidewall 312 and second sidewall 314. However, in embodiments, the one or more bridges 320 may not fully merge with or contact first dielectric material 306, so long as a strong contact is formed with first sidewall 312 and second sidewall 314.

Nonetheless, in embodiments, a metal oxide, such as aluminum oxide, may be utilized as one or more bridges 320. In such embodiments, the metal oxide may be physically connected to the adjacent channels but not in electrical connection. In such a manner, holes may still be attracted to the metal oxide without an electrical connection to the adjacent channels.

In embodiments, the one or more bridges 320 are only formed in a portion of shallow trench isolation 308. For instance, as illustrated in FIG. 3G, the one or more bridges 320 have a height slightly greater than a height of the exposed portion 322, and may therefore extend into protective liner 310. However, in embodiments, the one or more bridges 320 may have a height that is generally the same as the height of exposed portion 322. Namely, while the shallow trench isolation 308 may be fully filled with bridge 320 material above first dielectric material 306, such an embodiment may allow for undesired high electric fields at upper regions of the shallow trench isolation 308, such as within source/drain regions if protective liner 310 is not fully or evenly formed.

Nonetheless, in embodiments, operation 206 may include a recessing step that decreases a height of bridge(s) 320 from a first height, to a second height below the first height, as illustrated in FIG. 3H. In such embodiments, the bridge material may be recessed to be generally even with bottom surface 318 of protective liner 310. However, it should be understood that, in embodiments, such a recessing operation may not be necessary. For instance, in embodiments, the original bridge 320 formation may only occur to a level approximately even with bottom surface 318. Nonetheless, in embodiments, such a recessing may improve removal of protective liner 310, as will be discussed in greater detail below. Thus, the recessing, if utilized, may be conducted by any recessing methods as known in the art.

Regardless of whether operation 206 includes a recessing step, in embodiments, the thickness (measured from bridge bottom 324 to bridge top 326) of the one or more bridges 320 may be greater than or about 2 nm, such as greater than or about 4 nm, such as greater than or about 6 nm, such as greater than or about 8 nm, such as greater than or about 10 nm, such as greater than or about 12 nm, such as greater than or about 14 nm, such as greater than or about 16 nm, such as greater than or about 18 nm, such as greater than or about 20 nm, such as greater than or about 25 nm, such as greater than or about 30 nm, such as less than or about 70 nm, such as less than or about 60 nm, such as less than or about 50 nm, such as less than or about 40 nm, such as less than or about 35 nm, or any ranges or values therebetween. Namely, in embodiments, the thickness may be selected so as to provide enough contact area for a robust connection.

In addition, as discussed above, in embodiments, the one or more bridges are formed at approximately a center point of the two or more walls 305 (and therefore shallow trench isolation 308) between first and second source/drain regions, or such as between source/drain 304 and top surface 307. Namely, by utilizing a bridge at an approximate center point, or any one or more of the trench depths discussed above, of the two or more walls 305, greater support may be provided, as well as word line resistivity and/or hole distribution may be improved. However, it should be understood that in embodiments, more than one bridge 320 may be utilized between two respective walls 305, and neither or one of such bridges 320 may not be located at approximately a center point. For instance, as a first bridge 320 disposed adjacent to a source/drain region 304 and a second bridge 320 formed adjacent to a second source drain region of semiconductor structure 300. Nonetheless, regardless of the number of bridges utilized between two respective channels, adjacent channels may have a height extending between first and second source/drain regions, and at least one of the bridges 320 may be formed between adjacent channels at a height of about 20% to about 80% of the channel height, such as from about 30% to about 70%, such as from about 40% to about 60%, such as from about 45% to about 55%, or any ranges or values therebetween.

However, while FIGS. 3A-3H have discussed one method of forming bridge 320, in embodiments where only structural stability is desired, bridge 320 may be formed by other methods. For instance, in embodiments, after recessing the first dielectric material 306 as illustrated in FIG. 3B, the isolations 308 may be filled with any one or more bridge materials discussed above, with or without liner 310. After filling the bridge 320 material into isolation 308, the bridge material may be recessed to a desired thickness, such as any one or more of the thicknesses discussed above. Thus, the bridge 320 material may extend across the isolation 308 above the first dielectric material 306, similar to that illustrated in FIG. 3H.

Regardless of how the bridge is formed, after formation of the bridge at operation 206, the protective liner 310 may be removed, and the remainder of the shallow trench isolation 308 above bridge 320 may be filled at operation 207 as illustrated in FIG. 31. In embodiments, the protective liner 310 may be removed utilizing any methods as known in the art. For instance, in embodiments, the protective liner 310 may be removed by any etch process that does not damage channel(s) 305 and/or bridge 320. Thus, as illustrated, the second dielectric 332 may contact adjacent walls 305 as well as the top surface 326 of bridge 320.

In embodiments, the second dielectric material 332 may be the same dielectric material as first dielectric material 306 or a different dielectric material than initially filled in shallow trench isolation 308 in FIG. 3A. In embodiments, the first and/or second dielectric material 332 may be any one or more dielectric material(s), such as a silicon oxide, silicon oxycarbide, silicon oxynitride, silicon oxycarbonitride, combinations thereof, or other dielectric material as known in the art, formed utilizing any fill methods discussed above and as known in the art. Although the following description will regularly discuss silicon oxide or silicon nitride as a dielectric material and/or a spacer material, it is to be understood that any number of dielectric materials may be used in embodiments of the present technology, and the present technology should not be limited to any particular dielectric material in which features may be formed Nonetheless, as will be discussed in greater detail below, it should be understood that other materials may be utilized at operation 207.

After fill operation 207, the semiconductor structure 300 may undergo mask formation and word line trench formation at operation 208, followed by subsequent removal of dielectric material(s) 306, 332 at operation 209. For instance, FIG. 3J illustrates etching of walls 305 into channels 348 by etching in a direction extending in a second horizontal direction, utilizing mask 340. Namely, as discussed above for the formation of shallow trench isolations 308 between walls 305, a pattern or mask 340 defining second shallow trench isolations 346 may be used to form the isolations between channels 348, which run in a row parallel or in plane with word lines in this embodiment, formed by an etch process. The resulting channels 348 may have a uniform or nonuniform width, and/or a width generally equal to walls 305. The second shallow trench isolations 346 may serve to isolate neighboring channels 348.

However, unlike conventional processes where standalone pillars are formed during GAA word line processing, in embodiments, the mask 340 may be maintained on channels 348 during formation of the word line components. In such a manner, each channel in a respective row may be connected to adjacent channels by both bridge 320 and mask 340 extending in the word line direction. Thus, structure 300 according to the present technology may exhibit greatly enhanced structural stability during formation, as connections between at least a portion of the adjacent channels (e.g. channels adjacent along a word line) are maintained at a bottom surface 309, top surface 307, and at bridge 320 between source/drain regions 304. In such a manner, inconsistencies can be reduced and improved electrical properties may be exhibited even when the dielectric material(s) 306, 332 are removed for GAA formation.

Nonetheless, still referring to FIG. 3J, which illustrates the formation of a third dielectric material 450 along adjacent walls 305 and bridges 320 in rows extending in the first horizontal direction (e.g. such that third dielectric material 350 is generally parallel with the word line direction) at operation 210. The third dielectric material 350 may be formed from materials such as SiO or other similar materials, including any one or more of the dielectric materials discussed above. For example, in embodiments where the channel material is silicon, the third dielectric material may be SiO which may be oxidized from the walls 305 and/or 448 to be used as the dielectric material 450. However, in embodiments, third dielectric material (e.g. gate oxide) 350 may be any material and deposited as known in the art. Notwithstanding the method, the third dielectric material extends generally alone an external perimeter of the respective shallow trench isolation 346. The thickness of the third dielectric material may be between about 1 nm and about 10 nm.

Moving to FIG. 3K, the deposition of the gate or word line material 352 at operation 210 is illustrated. After the formation of third dielectric material 350, the material forming gate 352 is deposited on the third dielectric material 350 generally along an exterior perimeter of shallow trench isolation 346. In embodiments, the gate 352 may be a material such as a low-resistance metal, including as tungsten, titanium nitride, titanium, ruthenium, cobalt, molybdenum, the like, or combinations thereof.

At optional operation 211, the material forming gate 352 may be trimmed and/or bottom opened, as illustrated in FIG. 3L. For instance, in the illustrated embodiment, a gap g between adjacent gates 352 spaced apart in the bit line direction may be widened by trimming or removing a portion of gate material 352, such as by etching. Additionally or alternatively, the bottom may be “punched” according to any of the methods discussed above to separate adjacent gates 352. Furthermore, as illustrated, in embodiments, the gate material 352 may be etched back below mask layer 340. However, as will be discussed in greater detail in regards to FIG. 4A and 4B, it should be understood that, in embodiments, trimming and/or bottom punching may not be necessary.

Regardless, one or more remaining 4F² components may be formed at optional operation 212 as illustrated in FIG. 3M. For instance, spacer 354 has been formed in second shallow trench isolations 346 between adjacent channels 348. The spacer layer(s) 354 may be formed from any insulating material, such as SiO, SiN, low k dielectrics, or other similar materials. In embodiments, the spacer layer(s) 354 may be filled utilizing any method known in the art, and then etched back. For instance, in embodiments, the spacer layer 354 may be filled and etched back to a level below mask 340 to provide for recessing of the gate material 352, followed by a second fill of the same or different insulating material. In some embodiments, a planarization process may be performed to create a flat surface at the top of the stack for the formation of subsequent layers and/or to expose walls 305, 348.

Moreover, after formation of the remaining word line components, the semiconductor structure 300 may re-enter a normal process flow for a vertical cell DRAM array, such as a 4F² DRAM array, and undergo one or more further processing steps. For instance, the semiconductor structure 300 may undergo contact redistribution, bonding pad formation, and/or copper contact formation.

Notwithstanding the methods utilized to form the remaining word line components, the present disclosure has found that by utilizing bridge 320, improved resistivity and connection can be obtained between adjacent channels extending in the word line direction. Nonetheless, FIG. 4A illustrates where the word line 352 material has been deposited at a thickness such that the material merges from adjacent channels 348 until contact of the material from adjacent channels 348 (e.g. where the material deposited around the adjacent channels continues to be deposited until the materials “merge” between the channels) is obtained in addition to contact between the adjacent channels via bridge 320. Such an embodiment may also provide for thicker and more even deposition of the gate 352 material in addition to the other benefits discussed above.

However, the present technology has also found that the bridge 320 allows a targeted deposition of the material forming gate 352 as illustrated in FIG. 4B. As discussed above, in embodiments, the material forming gate 352 may be deposited at a specific thickness that is less than one-half of the gap distance between adjacent channels (g², which may be the gap distance between an oxide disposed on first and second channel sidewalls, in embodiments) or between adjacent word lines. Surprisingly, due to the presence of bridge 320, robust connection may be obtained without deposition at a thickness that would exhibit merging of the material forming gate 352 at a location between adjacent channels or between adjacent word lines. Thus, the present technology provides devices and methods for reducing the pitch of GAA 4F² memory cells while maintaining or even improving word line resistivity.

For instance, in embodiments, operation 210 may include depositing the word line 352 material at a thickness of less than or about 10 nm, such as less than or about 9 nm, such as less than or about 8 nm, such as less than or about 7.5 nm, such as less than or about 7 nm, such as less than or about 6.5 nm, such as less than or about 6 nm, such as less than or about 5 nm, such as less than or about 4.5 nm, such as less than or about 4 nm, such as less than or about 3.5 nm, such as less than or about 3 nm, such as less than or about 2.5 nm, such as less than or about 2 nm, or any ranges or values therebetween, over one or more channel or bridge surfaces of structure 300. For instance, in embodiments, the word line 352 material may be formed at any one or more of the above thicknesses over gate oxide 350 along trench perimeter and/or bridge 320.

Moreover, in embodiments, the present technology has found that by utilizing bridge 320 according to the present technology, a targeted and highly consistent gate 352 thickness may be achieved. For instance, in embodiments, gate 352 may have a thickness at any point along gate oxide 350 that is greater than or about 50% of an average thickness of the word line 352 material around a respective channel 348 or in a respective row extending in a word line direction, such as greater than or about 60%, such as greater than or about 70%, such as greater than or about 80%, such as greater than or about 85%, such as greater than or about 90%, such as greater than or about 92.5%, such as greater than or about 95%, such as greater than or about 97.5%, such as greater than or about 99%, such as greater than or about 99.5% of the average thickness of word line 352 material around a respective channel 348 or within a respective row extending in a word line direction.

Nonetheless, after formation of the word line components, the semiconductor structure 300 may re-enter a normal process flow for a vertical cell GAA DRAM array, such as a GAA 4F² DRAM array, and undergo one or more further processing steps. For instance, the semiconductor structure 300 may undergo contact redistribution, bonding pad formation, and/or copper contact formation. Nonetheless, semiconductor structure may exhibit a drastically reduced word line resistivity, improved structural stability, and/or reduced or even eliminated floating body effect due at least in part to the connection of at least a portion of the channels in a word line direction row to adjacent channels in the row.

It should be appreciated that the specific steps illustrated in the figures provide particular methods of forming a GAA 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A vertical cell dynamic random-access memory (DRAM) array, comprising:
a plurality of bit lines arranged in a first horizontal direction;
a plurality of channels extending in a vertical direction that is generally orthogonal to the first horizontal direction such that the plurality of bit lines intersect with a source/drain region of the plurality of channels;
a bridge extending between a first channel of the plurality of channels and a second channel of the plurality of channels, wherein the first channel is spaced apart from the second channel in a row extending in a second horizontal direction; and
a gate extending in the second horizontal direction and formed around at least a portion of the plurality of channels and the bridge.

2. The vertical cell dynamic random access memory (DRAM) array of claim 1, wherein the gate extends between the first channel and the second channel at a location above the bridge, below the bridge, and/or both above and below the bridge.

3. The vertical cell dynamic random access memory (DRAM) array of claim 1, wherein the gate has a thickness of less than or about 8 nm.

4. The vertical cell dynamic random access memory (DRAM) array of claim 1, wherein the gate has a thickness that is less than 50% of a gap width between the first channel and the second channel.

5. The vertical cell dynamic random access memory (DRAM) array of claim 1, wherein the bridge is formed from a dielectric material.

6. The vertical cell dynamic random access memory (DRAM) array of claim 1, wherein the bridge is formed from a substrate material.

7. The vertical cell dynamic random access memory (DRAM) array of claim 6, wherein the bridge is formed from a p-doped substrate material.

8. The vertical cell dynamic random access memory (DRAM) array of claim 1, further comprising at least a third channel of the plurality of channels spaced apart from the second channel in the row extending in the second horizontal direction, wherein a second bridge extends between the second channel and the third channel.

9. The vertical cell dynamic random access memory (DRAM) array of claim 8, wherein the gate extends around the second bridge.

10. The vertical cell dynamic random access memory (DRAM) array of claim 1, wherein the first channel and the second channel define a channel height between a first source/drain region of the respective channel and a top surface of the respective channel, wherein the bridge is disposed between the first channel and the second channel at a height that is from about 20% to about 80% of the channel height.

11. A vertical cell dynamic random access memory (DRAM) array, comprising:
a plurality of bit lines arranged in a first horizontal direction;
a plurality of word lines arranged in a second horizontal direction;
a first plurality of spaced apart channels in a first row extending in the second horizontal direction;
a second plurality of spaced apart channels in a second row extending in the second horizontal direction, spaced apart from the first row;
a plurality of bridges extending between adjacent channels in the first row and between adjacent channels in the second row; and
one or more gates, wherein the one or more gates extend around the first plurality of spaced apart channels and the plurality of bridges in the first row, the second plurality of spaced apart channels and the plurality of bridges in the second row, or both the first plurality of spaced apart channels and the plurality of bridges in the first row and the second plurality of spaced apart channels and the plurality of bridges in the second row,
wherein each of the channels extends in a vertical direction that is generally orthogonal to the first horizontal direction and the second horizontal direction such that the plurality of bit lines intersect with a source/drain region of the plurality of channels.

12. The vertical cell dynamic random access memory (DRAM) array according to claim 11, wherein the one or more gates extends between adjacent channels in the first row and/or the second row at a location above the bridge, below the bridge, and/or both above and below the bridge.

13. The vertical cell dynamic random access memory (DRAM) array according to claim 11, wherein the one or more gates have a thickness that is less than 50% of a gap width between adjacent channels in the first row and/or second row.

14. A method of forming a vertical cell dynamic random-access memory (DRAM) array, comprising:
etching a substrate to form one or more shallow trench isolations extending in a first horizontal direction and a plurality of vertically extending walls having a first source/drain region at a second end of the vertically extending walls;
forming a dielectric material in the one or more of the shallow trench isolations;
recessing the dielectric material to a first depth in the one or more shallow trench isolations;
forming a bridge in the one or more shallow trench isolations, wherein the bridge contacts a first sidewall of a first wall and a second sidewall of a second wall of the plurality of vertically extending walls;
depositing a mask over a first end of the vertically extending walls;
etching one or more second trenches extending in a second horizontal direction, forming at least a first channel and a second channel;
depositing a gate material around the first channel, the second channel, and the bridge.

15. The method of claim 14, wherein the gate material is deposited at a thickness of less than 50% of a width of one or more of the second trenches.

16. The method of claim 14, wherein the gate material is deposited until a gate material deposited around the first channel and a gate material deposited around the second channel merge in the respective shallow trench isolation.

17. The method of claim 16, further comprising removing at least a portion of the gate material in the one or more second trenches.

18. The method of claim 14, further comprising maintaining the mask during etching of the one or more second trenches and the depositing of the gate material.

19. The method of claim 14, further comprising recessing the bridge from a first height to a second height below the first height prior to depositing the gate material.

20. The method of claim 14, further comprising forming a protective liner in the one or more shallow trench isolations after recessing the dielectric material to a first depth, and recessing the dielectric material to a second depth in the one or more shallow trench isolations below the first depth.
